(19) United States
(12) Patent Application Publication
(10) Pub. No.: US 2026/0304929 A1
(43) Pub. Date: Oct. 1, 2026

(54) SEMICONDUCTOR DEVICES AND METHODS OF FORMING THE SAME

(71) Applicant: Taiwan Semiconductor Manufacturing Company, Ltd., Hsin-Chu (TW)

(72) Inventor: Ka-Hing Fung, Zhudong Township (TW)

(21) Appl. No.: 19/093,621

(22) Filed: Mar. 28, 2025

(51) Int. Cl. H10D 84/83; H10D 30/00; H10D 30/01; H10D 30/43; H10D 62/10; H10D 62/13; H10D 62/60; H10D 62/832; H10D 64/01; H10D 84/01

(52) U.S. Cl. CPC H10D 84/832; H10D 30/014; H10D 30/0191; H10D 30/43; H10D 30/502; H10D 62/102; H10D 62/121; H10D 62/151; H10D 62/60; H10D 62/832; H10D 64/017; H10D 84/013; H10D 84/0151; H10D 84/8312

(57) ABSTRACT

Semiconductor structures and methods are provided. An exemplary method according to the present disclosure includes forming a patterned hard mask over a substrate, the patterned hard mask comprising an opening exposing a portion of the substrate, removing the portion of the substrate, thereby forming a trench in the substrate, epitaxially forming a first semiconductor layer in and over the trench, the first semiconductor layer and the substrate comprising different compositions, selectively removing the patterned hard mask after the epitaxially forming of the first semiconductor layer, planarizing the first semiconductor layer and the substrate, forming a second semiconductor layer on the first semiconductor layer and the substrate after the planarizing, and forming an n-type gate-all-around (GAA) transistor over the first semiconductor layer and the substrate.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of IC structures and fabrication processes. For example, improving device performance becomes more challenging when device sizes continue to decrease. Although methods for addressing such a challenge have been generally adequate, they have not been entirely satisfactory in all aspects.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

FIG. 1 is a flowchart illustrating a method of forming a semiconductor structure, according to various embodiments of the present disclosure.

FIGS. 2, 3, 4, 5, 6, 7, 8, 9, 11, 16, and 22 illustrate fragmentary cross-sectional views of the semiconductor structure during different fabrication stages in the method of FIG. 1, according to various aspects of the present disclosure.

FIGS. 10A, 12A, 13A, 14A, 15A, 17A, 18A, 19A, 20A, and 21A illustrate fragmentary cross-sectional views of the semiconductor structure taken along line A-A′ shown in FIG. 9 during different fabrication stages in the method of FIG. 1, according to various aspects of the present disclosure.

FIGS. 10B, 12B, 13B, 14B, 15B, 17B, 18B, 19B, 20B, and 21B illustrate fragmentary cross-sectional views of the semiconductor structure taken along line B-B′ shown in FIG. 9 during different fabrication stages in the method of FIG. 1, according to various aspects of the present disclosure.

FIGS. 23A, 23B, 24A, and 24B illustrates fragmentary cross-sectional views of an alternative semiconductor structure during different fabrication stages in the method of FIG. 1, according to various aspects of the present disclosure.

FIGS. 25, 26, and 27 illustrates fragmentary cross-sectional views of different fabrication stages of an alternative hybrid substrate that can be implemented to form the semiconductor structure thereon, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed. For avoidance of doubts, the X, Y and Z directions in the figures are perpendicular to one another and are used consistently. Throughout the present disclosure, like reference numerals denote like features unless otherwise excepted.

An n-type transistor (e.g., NFET) includes a pair of n-type doped source/drain features, and its majority carrier is electrons. A p-type transistor (PFET) includes a pair of p-type doped source/drain features, and its majority carrier is holes. The present disclosure includes forming a substrate that includes a stressor configured to increase the carrier mobility of electrons without adversely affecting the carrier mobility of holes. Thus, performances of NFETs may be improved.

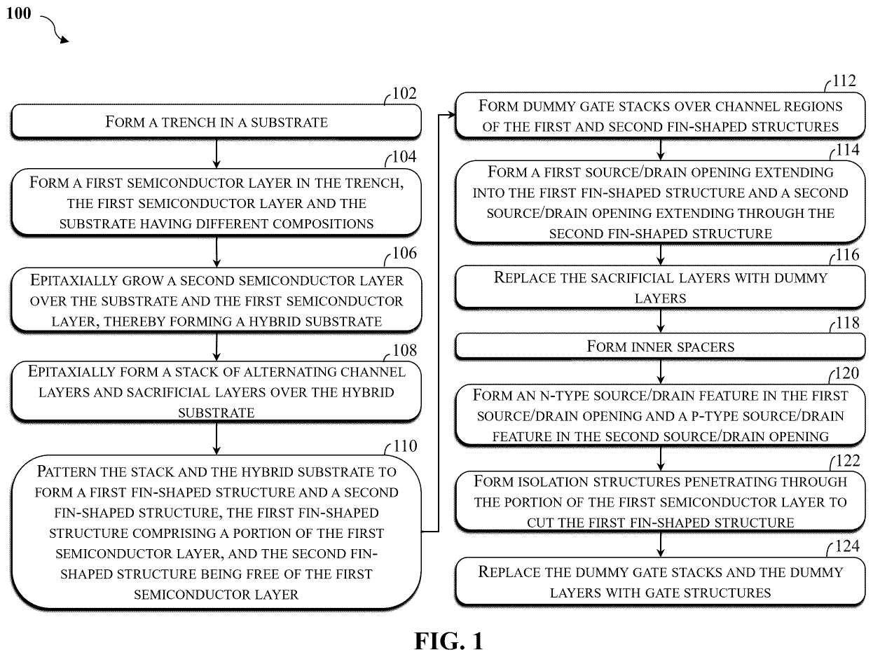

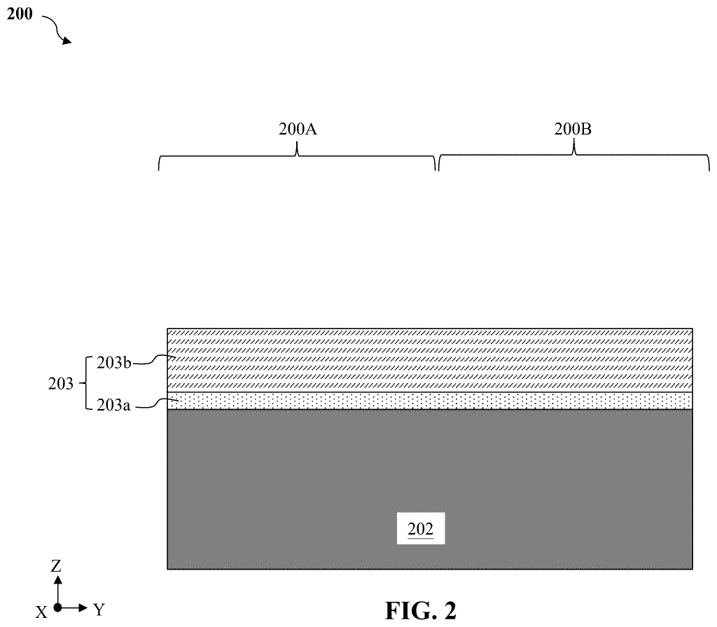

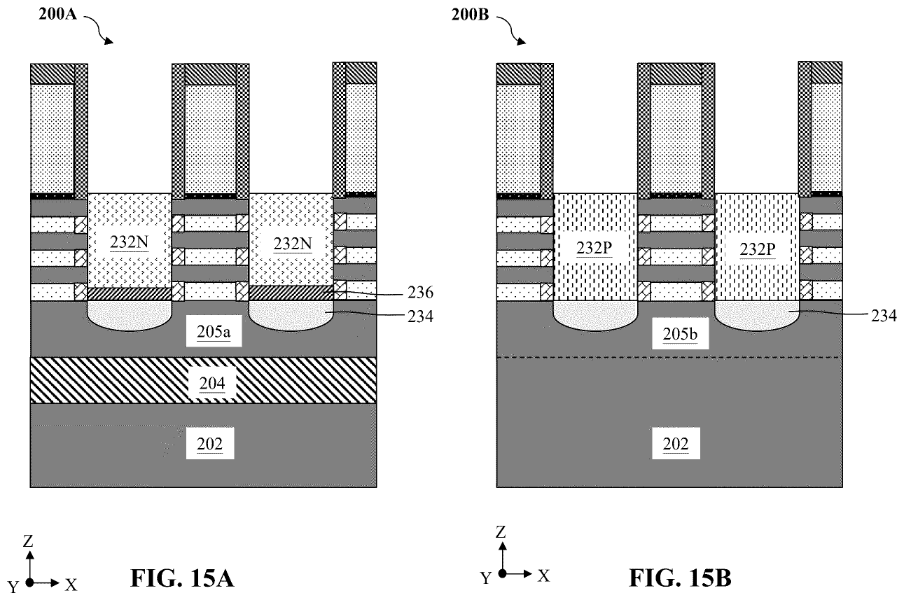

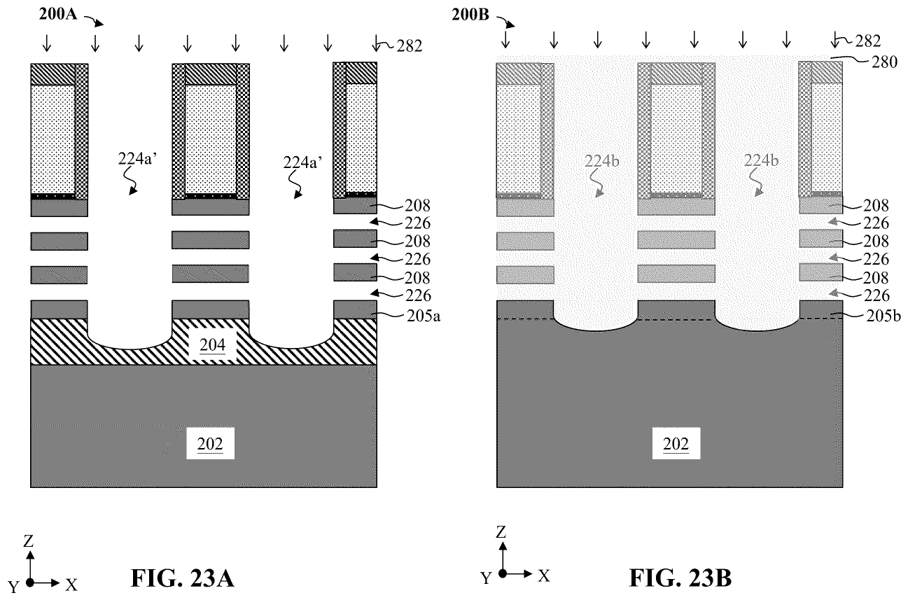

The various aspects of the present disclosure will now be described in more detail with reference to the figures. In that regard, FIG. 1 is a flowchart illustrating method 100 of forming a semiconductor structure 200 according to embodiments of the present disclosure. Method 100 is described below in conjunction with FIGS. 2-22, which are fragmentary cross-sectional views or top views of the semiconductor structure 200 at different stages of fabrication according to embodiments of method 100. FIGS. 23A-27 represent alternative embodiments or various aspects of the present disclosure. Method 100 is merely an example and is not intended to limit the present disclosure to what is explicitly illustrated therein. Additional steps may be provided before, during, and/or after the method 100, and some steps described can be replaced, eliminated, or moved around for additional embodiments of the method. Not all steps are described herein in detail for reasons of simplicity. Structure showing various intermediate stages of the semiconductor structure 200 may be referred to as intermediate structure 200.

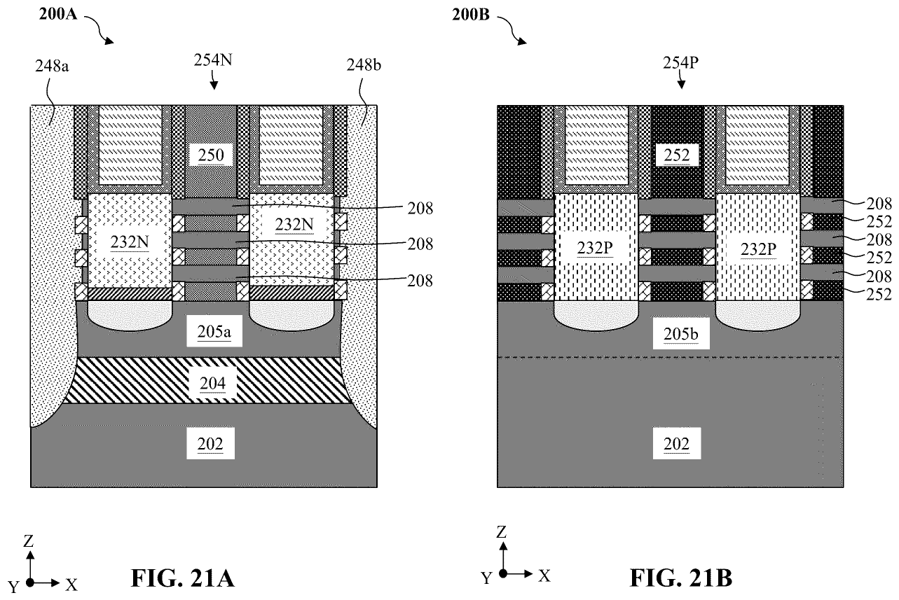

Referring to FIGS. 1 and 2-3, method 100 includes a block 102 where a trench 202T is formed in a substrate 202. With reference to FIG. 2, an intermediate structure 200 is received. In this illustrated embodiment, the intermediate structure 200 includes a first device region 200A for forming n-type devices (e.g., n-type gate-all-around (GAA) transistor 254N shown in FIG. 21A) and a second device region 200B for forming p-type devices (e.g., p-type GAA transistor 254P shown in FIG. 21B).

The intermediate structure 200 includes a substrate 202. In an embodiment, the substrate 202 is a bulk silicon substrate (i.e., including bulk single-crystalline silicon). The substrate 202 may include other semiconductor materials in various embodiment, such as germanium, silicon carbide, gallium arsenide, gallium phosphide, indium phosphide, indium arsenide, indium antimonide, SiGe, GaAsP, AlInAs, AlGaAs, GaInAs, GaInP, GaInAsP, or combinations thereof. In some alternative embodiments, the substrate 202 may be a semiconductor-on-insulator substrate, such as a silicon-on-insulator (SOI) substrate, a silicon germanium-on-insulator substrate, or a germanium-on-insulator substrate, and includes a carrier, an insulator on the carrier, and a semiconductor layer on the insulator. The substrate 202 can include various doped regions configured according to design requirements of semiconductor structure 200. P-type doped regions may include p-type dopants, such as boron, indium, other p-type dopant, or combinations thereof. N-type doped regions may include n-type dopants, such as phosphorus, arsenic, other n-type dopant, or combinations thereof. In some implementations, the substrate 202 includes doped regions formed with a combination of p-type dopants and n-type dopants. The various doped regions can be formed directly on and/or in substrate 202, for example, providing a p-well structure, an n-well structure, a dual-well structure, a raised structure, or combinations thereof. An ion implantation process, a diffusion process, and/or other suitable doping process can be performed to form the various doped regions.

With reference to FIG. 2, a hard mask 203 is formed on the substrate 202. In an illustrated embodiment, the hard mask 203 includes a first layer 203a and a second layer 203b over the first layer 203a and having a material composition different than the first layer 203a. In an embodiment, the first layer 203a includes an oxide layer, and the second layer 203b includes a nitride layer (e.g., silicon nitride). A thickness of the second layer 203b may be greater than the first layer 203a. In some other embodiments, the hard mask 203 may be a single layer structure and may be formed of, for example, silicon nitride.

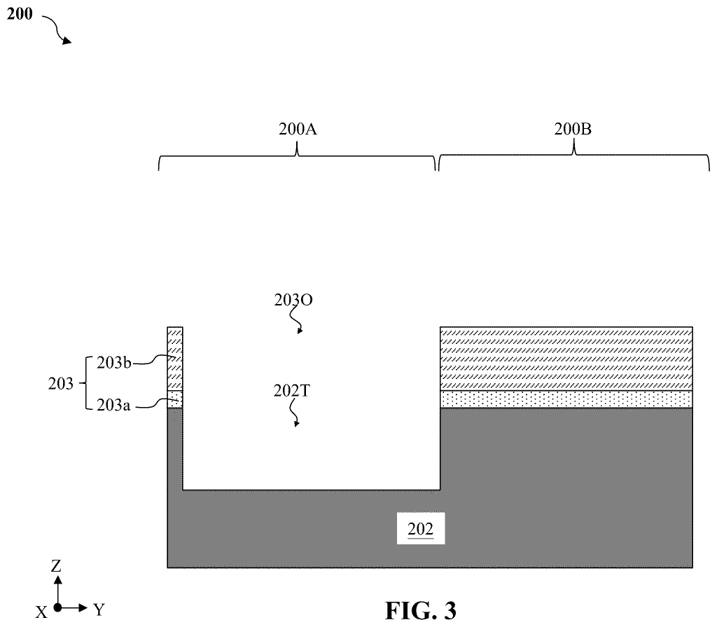

With reference to FIG. 3, using photolithography and etching processes, the hard mask 203 is patterned. The photolithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The etching process may include dry etching, wet etching, and/or other etching methods. After patterning, the patterned hard mask 203 includes an opening 203O exposing a portion of the substrate 202. While using the patterned hard mask 203 as an etch mask, an etching process is performed to form a trench 202T in the substrate 202. The opening 203O and the trench 202T are in the first device region 200A.

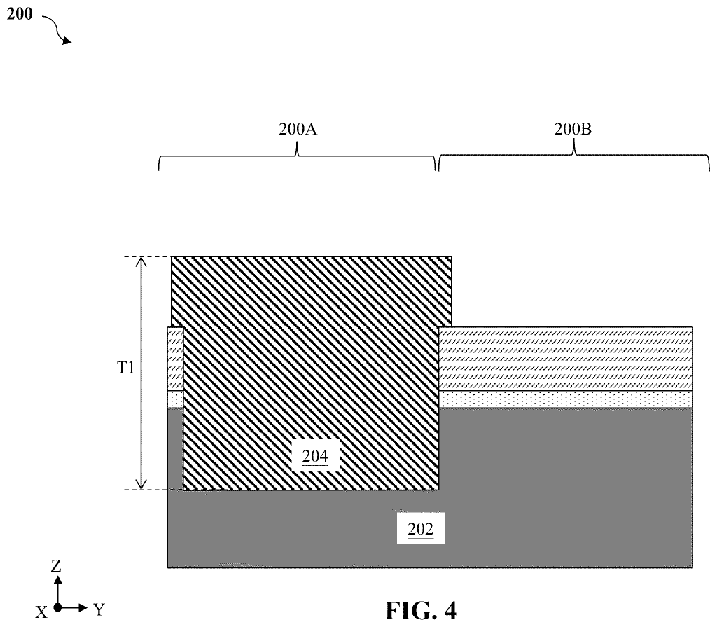

Referring to FIGS. 1 and 4-7, method 100 includes a block 104 where a first semiconductor layer 204 is formed in the trench 202T. In an exemplary process, with reference to FIG. 4, the first semiconductor layer 204 is deposited in and over the trench 202T using an epitaxy process. Suitable epitaxy processes include vapor-phase epitaxy (VPE), ultra-high vacuum chemical vapor deposition (UHV-CVD), molecular beam epitaxy (MBE), and/or other suitable processes. As illustrated by FIG. 4, the deposited first semiconductor layer 204 fills the trench 202T, the opening 203O and may extend over a portion of the patterned hard mask 203. The first semiconductor layer 204 can include various doped regions configured according to design requirements of semiconductor structure 200. In this embodiment, n-type transistors (e.g., n-type transistor 254N shown in FIG. 21A) will be formed over the first semiconductor layer 204, and the first semiconductor layer 204 may include a doped region (not shown) having p-type dopants, such as boron, indium, other p-type dopant, or combinations thereof. An ion implantation process, a diffusion process, and/or other suitable doping process can be performed to form the doped region. In the present disclosure, to increase the performance of the n-type transistors, a composition of the first semiconductor layer 204 is selected such that it can induce strain into the n-type transistors. In various embodiments, the first semiconductor layer 204 may include silicon germanium, indium arsenide, gallium arsenide, gallium indium arsenide, or other suitable materials. In an embodiment, the first semiconductor layer 204 is formed of silicon germanium. A germanium content of the first semiconductor layer 204 may be about 30% to about 70%. If the germanium content is less than about 30%, then it may not induce enough strain to improve the device performance; and if the germanium content is greater than about 70%, a large number of dislocations may be formed during the epitaxial growth process of the first semiconductor layer 204, disadvantageously affecting the film quality of the first semiconductor layer 204. In some instances, the dislocations may even cause cracks in the first semiconductor layer 204. In an embodiment, the first semiconductor layer 204 has a deposition thickness T1. The deposition thickness T1 may be about 5nm to about 50 nm. If the deposition thickness T1 is less than about 5 nm, then it may not induce enough strain to improve the device performance; and if the deposition thickness T1 is greater than about 50 nm, cracks may be formed in the first semiconductor layer 204.

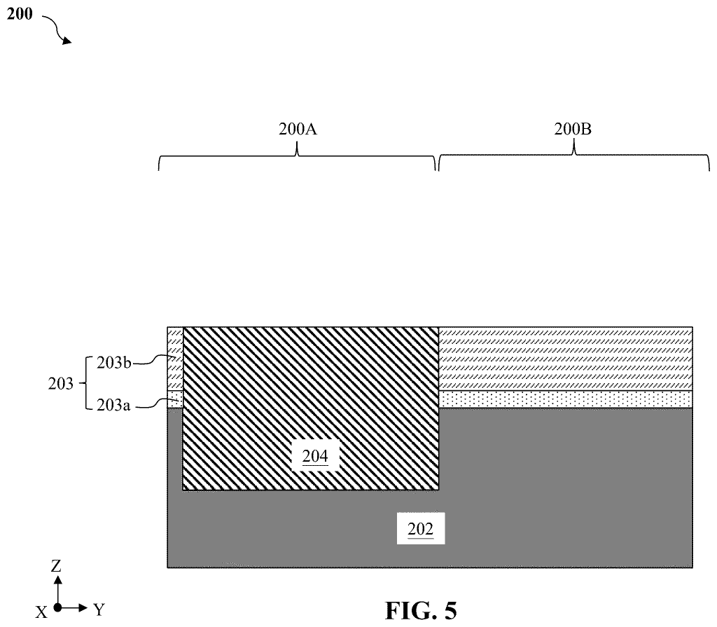

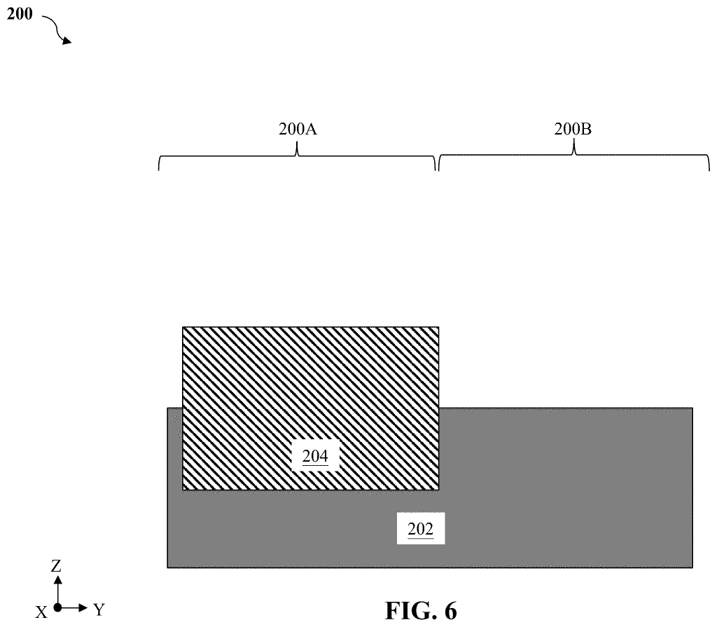

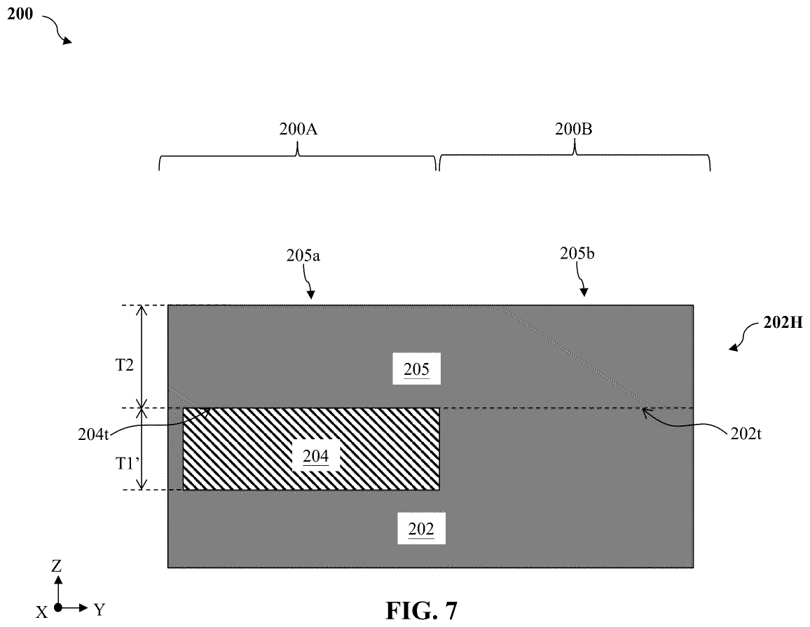

With reference to FIG. 5, after forming the first semiconductor layer 204, a first planarization process (e.g., chemical mechanical polishing) may be performed to remove a portion of the first semiconductor layer 204 extending over the patterned hard mask 203. With reference to FIG. 6, an etching process is performed to selectively remove the patterned hard mask 203 without substantially etching the first semiconductor layer 204 and the substrate 202. After performing the etching process, a top surface of the substrate 202 is exposed. With reference to FIG. 7, a second planarization process (e.g., chemical mechanical polishing) is performed to define a final thickness T1′ of the first semiconductor layer 204. The second planarization process may remove an upper portion of the first semiconductor layer 204 and a portion of the substrate 202. In an embodiment, upon completion of the second planarization process, the first semiconductor layer 204 has a top surface 204t, the substrate 202 has a top surface 202t that is coplanar with the top surface 204t. In some embodiments, the first semiconductor layer 204 may have a high germanium concentration. Due to mismatched lattice structures between the first semiconductor layer 204 and the substrate 202, dislocations may form during the epitaxial growth process of the first semiconductor layer 204. The performing of the second planarization process may remove a substantial amount of the dislocations and thus facilitate the formation of high-quality epitaxial layers (e.g., layers 205, 206, 208) in subsequent processes.

Referring to FIGS. 1 and 7, method 100 includes a block 106 where a second semiconductor layer 205 is epitaxially grown from the first semiconductor layer 204 and the substrate 202. In the present disclosure, to generate tensile strain, a composition of the second semiconductor layer 205 is selected such that it has a smaller lattice structure than the first semiconductor layer 204. In an embodiment, the second semiconductor layer 205 is formed of silicon. The second semiconductor layer 205 has a first portion 205a disposed directly over the first semiconductor layer 204 and in the first device region 200A and a second portion 205b laterally adjacent to the first portion 205a and in the second device region 200B. Due to the existence of the first semiconductor layer 204, lattice structure of the first portion 205a of the second semiconductor layer 205 may be stretched and undergo tensile strain, and the first portion 205a of the second semiconductor layer 205 may have dimensional larger crystal lattice cells than the second portion 205b of the second semiconductor layer 205. The second semiconductor layer 205 can include various doped regions configured according to design requirements of semiconductor structure 200. In this embodiment, n-type transistors will be formed over the first semiconductor layer 204, and second semiconductor layer 205 may include a first doped region (not shown) in the first portion 205a and a second doped region (not shown) in the second portion 205b. The first doped region includes p-type dopants, such as boron, indium, other p-type dopant, or combinations thereof, and the second doped region includes n-type dopants, such as phosphorus, arsenic, other n-type dopant, or combinations thereof. Ion implantation processes, diffusion processes, and/or other suitable doping process can be performed to form the first doped region and the second doped region.

The second semiconductor layer 205 may be deposited over the first semiconductor layer 204 and the substrate 202 using an epitaxy process. Suitable epitaxy processes include vapor-phase epitaxy (VPE), ultra-high vacuum chemical vapor deposition (UHV-CVD), molecular beam epitaxy (MBE), and/or other suitable processes. After the epitaxy process, a planarization process is performed to the intermediate structure 200, thereby providing a planar top surface. In an embodiment, after the planarization process, the second semiconductor layer 205 has a thickness T2. The thickness T2 may be about 5 nm to about 50 nm. If the thickness T2 is less than about 5 nm, it would be difficult to form satisfactory source/drain features; and if the deposition thickness T2 is greater than about 50 nm, the first semiconductor layer 204 may not be able to provide satisfactory stress to devices formed over the second semiconductor layer 205. For ease of description, the intermediate structure 200 illustrated by FIG. 7 may be referred to as a hybrid substrate 202H, and the first semiconductor layer 204 of the hybrid substrate 202H may function as a stressor and may be referred to as the stressor 204.

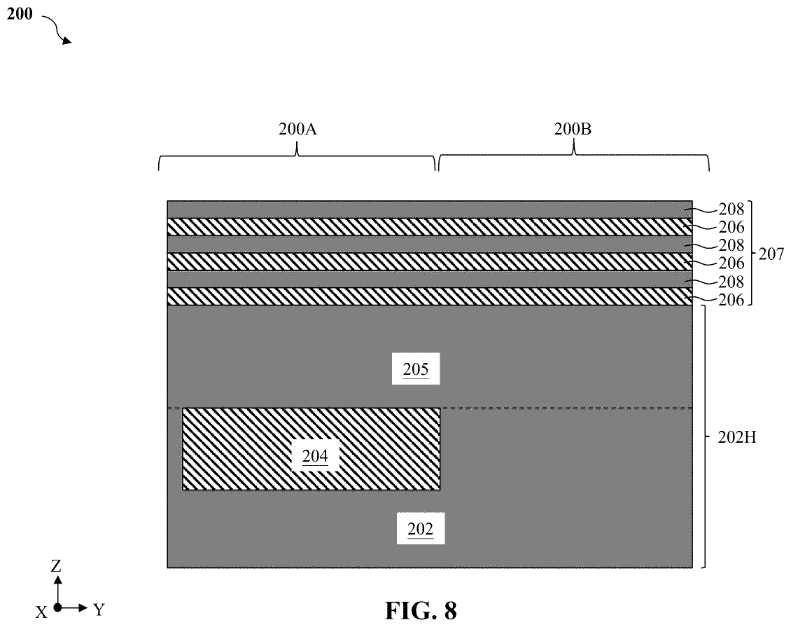

Referring to FIGS. 1 and 8, method 100 includes a block 108 where a stack 207 of alternating channel layers 208 and sacrificial layers 206 are formed over the hybrid substrate 202H. The channel layers 208 and the sacrificial layers 206 may be epitaxially deposited on the substrate 202 using molecular beam epitaxy (MBE), vapor-phase epitaxy (VPE), ultra-high vacuum CVD (UHV-CVD), and/or other suitable epitaxial growth processes. Each channel layer 208 may include a semiconductor material such as, silicon, germanium, silicon carbide, silicon germanium, GeSn, SiGeSn, SiGeCSn, other suitable semiconductor materials, or combinations thereof, while each sacrificial layer 206 has a composition different from that of the channel layer 208. In an embodiment, the channel layer 208 includes silicon (Si), the sacrificial layer 206 includes silicon germanium (SiGe). In these implementations, the additional germanium content in the sacrificial layers 206 allows selective removal or recess of the sacrificial layers 206 without inducing substantial damages to the channel layers 208. Germanium content of the sacrificial layer 206 may be about 20% to about 30%. If the germanium content of the sacrificial layer 206 is lower than about 20%, etch selectivity between the sacrificial layer 206 and the channel layer 208 is not high enough to allow selective removal or recess of the sacrificial layers 206 without inducing substantial damages to the channel layers 208; and if the germanium content of the sacrificial layer 206 is greater than about 30%, a larger amount of germanium may diffuse into the channel layer 208, affecting the performance of the transistors. In an embodiment, germanium content of the sacrificial layer 206 is lower than germanium content of the first semiconductor layer 204. In this depicted example, the stack 207 includes three sacrificial layers 206 interleaved by three channel layers 208. In some other examples, the stack 207 may include a total of three to ten pairs of alternating sacrificial layers 206 and channel layers 208; of course, other configurations may also be applicable depending upon specific design requirements.

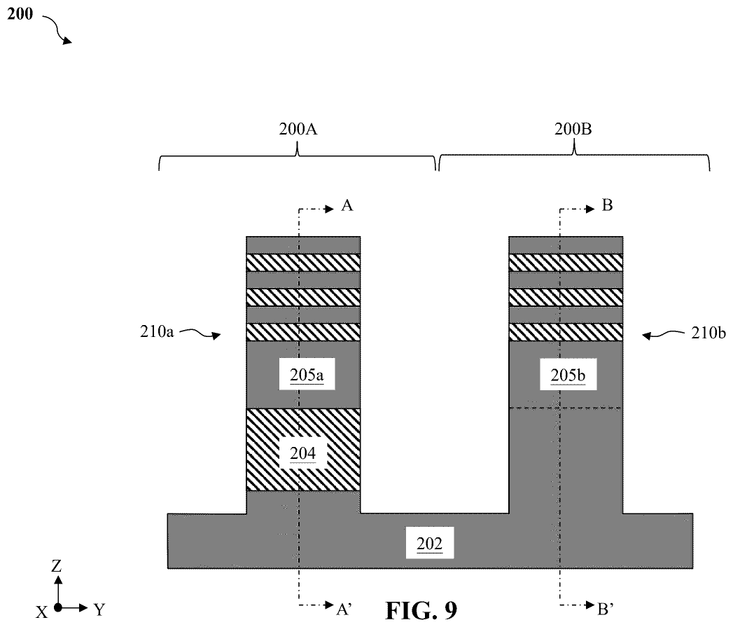

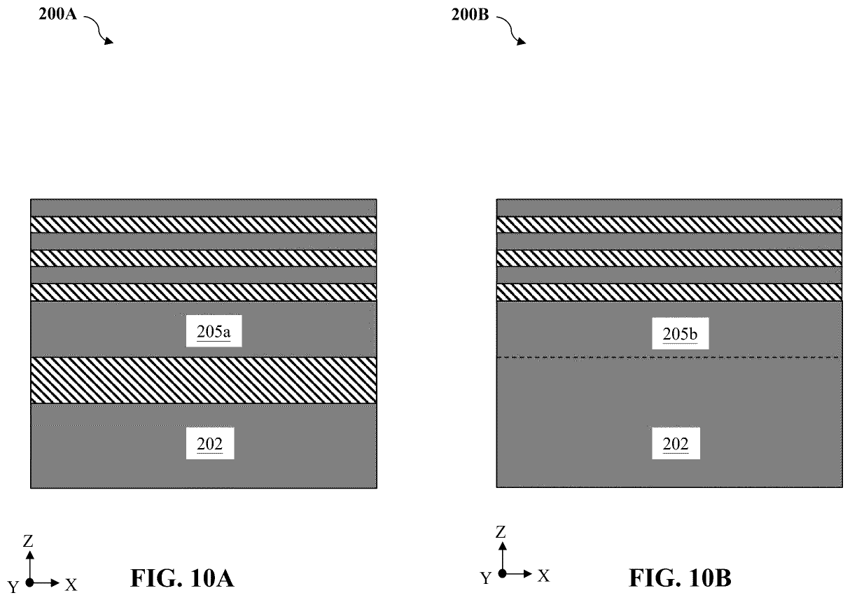

Referring to FIGS. 1, 9, and 10A-10B, method 100 includes a block 110 where the stack 207 and a top portion of the hybrid substrate 202H are patterned to form a fin-shaped structure 210a in the first device region 200A and a fin-shaped structure 210b in the second device region 200B. FIG. 10A depicts a fragmentary cross-sectional view of the semiconductor structure 200 taken along line A-A′ shown in FIG. 9, and FIG. 10B depicts a fragmentary cross-sectional view of the semiconductor structure 200 taken along line B-B′ shown in FIG. 9. As shown in FIGS. 9 and 10A-10B, each of the fin-shaped structures 210 a and 210 b extends vertically along the Z direction from the hybrid substrate 202H and extends lengthwise along the X direction. The patterned portion of the hybrid substrate 202H may be referred to as a protrusion, a mesa, or a base fin. For patterning purposes, a hard mask layer may be deposited over the stack 207. The hard mask layer may be a single layer or a multilayer. In one example, the hard mask layer includes a silicon oxide layer and a silicon nitride layer over the silicon oxide layer. The fin-shaped structures 210a-210b may be patterned using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used as an etch mask to etch the stack 207 and the hybrid substrate 202H to form the fin-shaped structures 210a-210b. As illustrated by FIGS. 9 and 10A-10B, the fin-shaped structure 210a includes parts of the substrate 202, the first semiconductor layer 204, the first portion 205a of the second semiconductor layer 205, and the stack 207, and the fin-shaped structure 210b includes parts of the substrate 202, the second portion 205b of the second semiconductor layer 205, and the stack 207. That is, the fin-shaped structure 210a includes the stressor, while the fin-shaped structure 210b does not include the stressor.

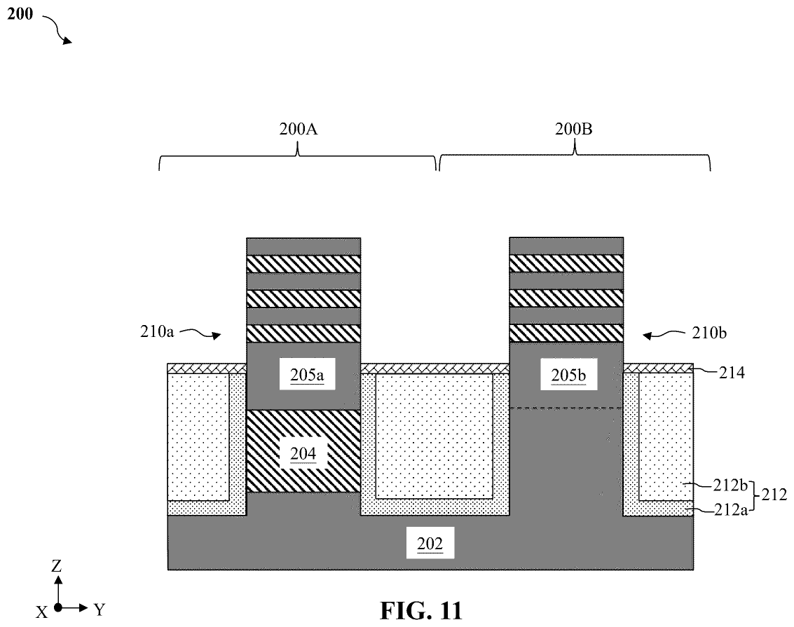

With reference to FIG. 11, after forming the fin-shaped structures 210a and 210b, an isolation feature 212 (e.g., a shallow trench isolation (STI) feature) is subsequently formed to provide isolation between two adjacent fin-shaped structures. The isolation feature 212 may include silicon oxide, silicon oxynitride, fluorine-doped silicate glass (FSG), a low-k dielectric, combinations thereof, and/or other suitable materials. In this illustrated embodiment, the isolation feature 212 includes a dielectric liner 212a (e.g., oxide) and a dielectric filler 212b (e.g., oxide) on the dielectric liner 212a. Top surfaces of the dielectric liner 212a and the dielectric filler 212b are substantially coplanar. The dielectric liner 212a may have a uniform thickness. A top surface of the isolation feature 212 is lower than a top surface of the mesa. In some implementations, the top surface of the isolation feature 212 may be a curved (e.g., concave) surface having a lowest point near its middle. In this illustrated embodiment, a top surface of the isolation feature 212 is below a top surface of the first portion 205a of the second semiconductor layer 205 and above a bottom surface of the first portion 205a of the second semiconductor layer 205. In some embodiments, to prevent the isolation feature 212 from being substantially etched during subsequent processes (e.g., removal of dummy layers 228 that will be performed at block 110), a protection layer 214 is formed on the isolation feature 212. Etch selectivity between the dummy layers 228 and the protection layer 214 is higher than etch selectivity between the dummy layers 228 and the isolation feature 212. In an embodiment, the protection layer 214 includes silicon nitride.

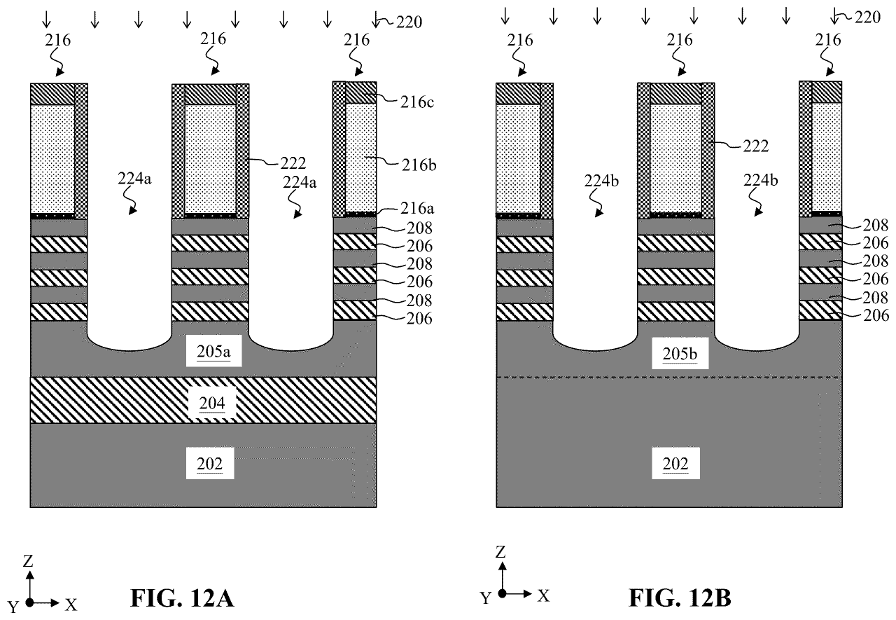

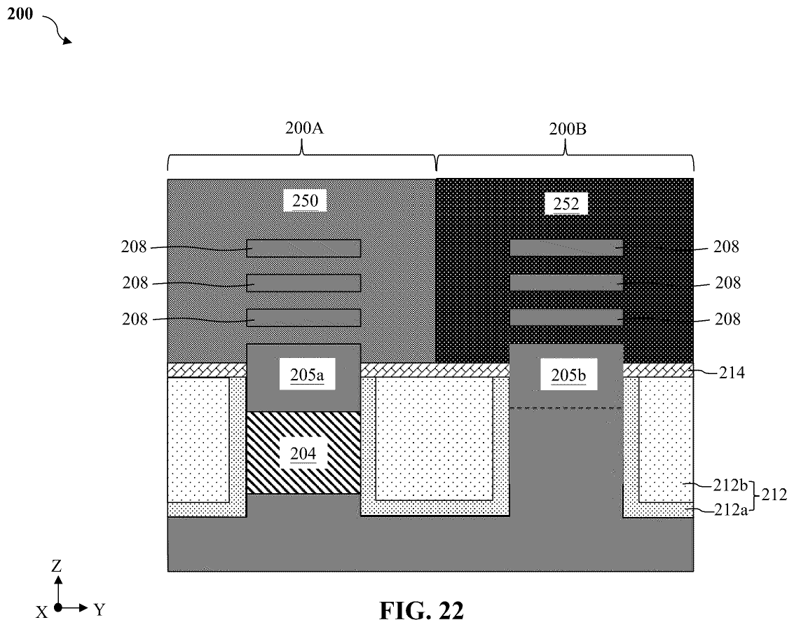

Referring to FIGS. 1 and 12A-12B, method 100 includes a block 112 where dummy gate stacks 216 are formed over the fin-shaped structures 210a and 210b. Dummy gate stacks 216 are formed over channel regions of the fin-shaped structures 210a and 210b. The channel regions and the dummy gate stacks 216 also define source/drain regions that are not vertically overlapped by the dummy gate stacks 216. Each of the channel regions is disposed between two source/drain regions along the X direction. Source/drain region(s) may refer to a source region or a drain region, individually or collectively dependent upon the context. In this embodiment, a gate replacement process (or gate-last process) is adopted where the dummy gate stacks 216 serve as placeholders for functional gate structures (e.g., functional gate structures 250, 252 shown in FIGS. 21A-21B and 22). Other processes for forming the functional gate structures are possible. In the present embodiments, each of the dummy gate stacks 216 includes a dummy gate dielectric layer 216a (e.g., silicon oxide), a dummy gate electrode 216b (e.g., polysilicon) disposed over the dummy gate dielectric layer 216a, and a gate-top hard mask 216c over the dummy gate electrode 216b.

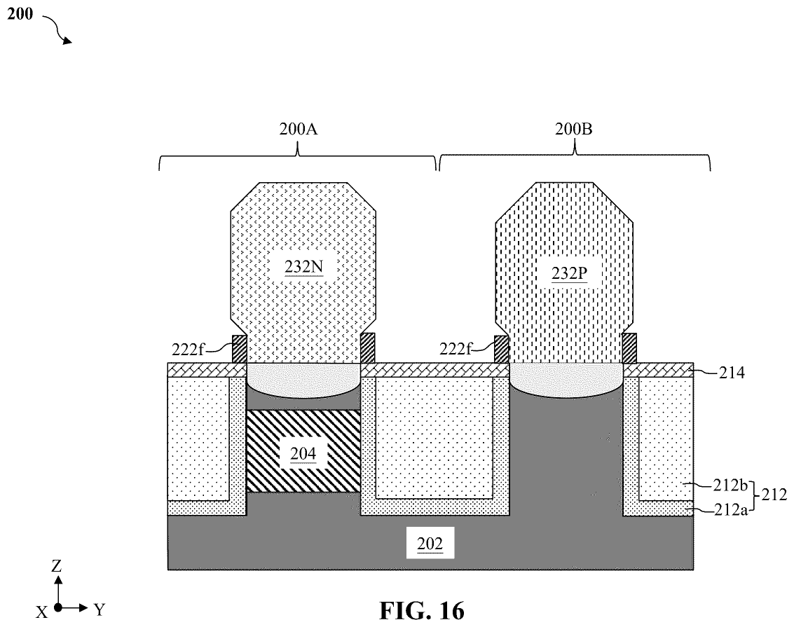

Still referring to FIGS. 1 and 12A-12B, method 100 includes a block 114 where source/drain openings 224a and source/drain openings 224b are formed to extend into the fin-shaped structures 210a-210b, respectively. Operations at block 114 may include formation of gate spacers 222 over the sidewalls of the dummy gate stacks 216 before the source/drain regions are recessed. In some embodiments, the formation of the gate spacers 222 includes deposition of one or more dielectric layers over the intermediate structure 200. In an example process, the one or more dielectric layers are conformally deposited using CVD, SACVD, or atomic layer deposition (ALD). The one or more dielectric layers may include silicon oxide, silicon nitride, silicon carbide, silicon oxynitride, silicon carbonitride, silicon oxycarbide, silicon oxycarbonitride, and/or combinations thereof. In an embodiment, the deposition and etch back process at block 114 further forms fin sidewall spacers 222f (shown in FIG. 16). That is, the sidewall spacers 222f and the gate spacers 222 are formed simultaneously. After the formation of the gate spacers 222, an etching process 220 is performed to the intermediate structure 200 to form the source/drain openings 224a in the first device region 200A and the source/drain openings 224b in the second device region 200B. The etching process 220 at block 114 may be a dry etch process or other suitable etch process. An example dry etching process may implement an oxygen-containing gas, hydrogen, a fluorine-containing gas (e.g., CF₄, SF₆, NF₃, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. In some embodiments, the etching process 220 at block 114 does not substantially etch the hybrid substrate 202H. In some other embodiments, the source/drain openings 224a-224b may extend into the hybrid substrate 202H. As shown in FIGS. 12A-12B, sidewalls of the sacrificial layers 206 and the channel layers 208 in the channel regions are exposed in the source/drain openings 224a or 224b. In this illustrated embodiment, the source/drain opening 224a does not extend into the first semiconductor layer 204.

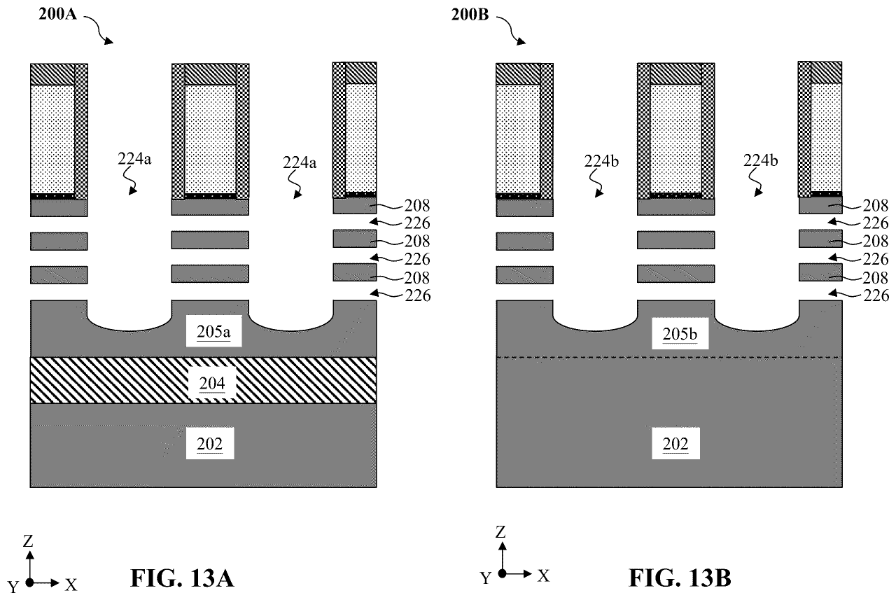

Referring to FIGS. 1, 13A-13B, and 14A-14B, method 100 includes a block 116 where the sacrificial layers 206 are replaced with dummy layers 228. With reference to FIGS. 13A-13B, after the formation of the source/drain openings 224a-224b, the sacrificial layers 206 interleaving the channel layers 208 in the channel region are selectively removed. The selective removal of the sacrificial layers 206 releases the channel layers 208 to form channel members 208 (“channel release process”). Depending on the design, the channel members 208 may take form of nanowires, nanosheets, or other nanostructures. The selective removal of the sacrificial layers 206 forms spaces 226 between and around adjacent channel members 208. The selective removal of the sacrificial layers 206 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture).

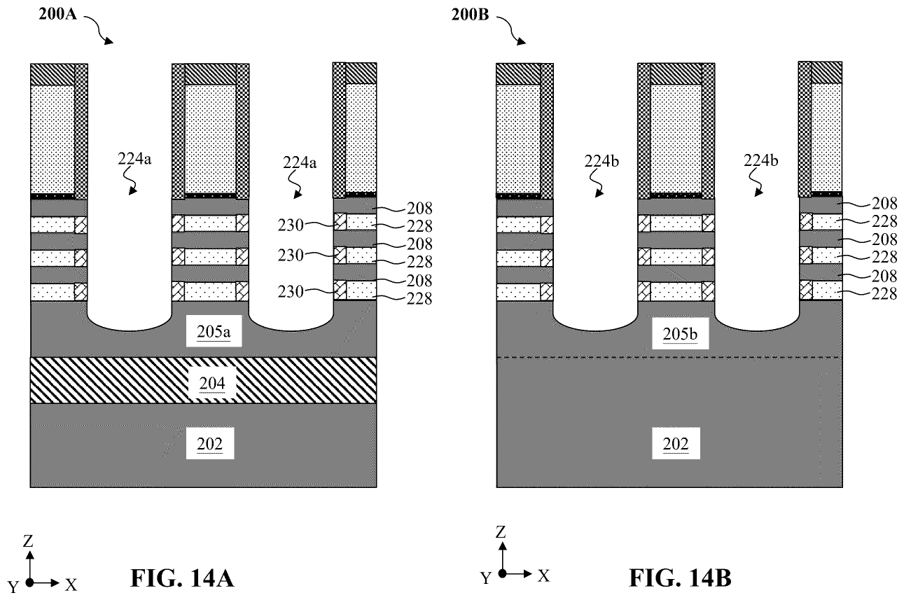

With reference to FIGS. 14A-14B, after the selective removal of the sacrificial layers 206, in an example process, a dielectric material layer is deposited around the channel members 208 and over the source/drain openings 224a-224b. The dielectric material layer fills the spaces 226 among the channel members 208 and covers end sidewalls of the channel members 208. After the deposition of the dielectric material layer, an etching process is performed to selectively etch the dielectric material layer, thereby forming the dummy layers 228 interleaved by the channel members 208. The dummy layers 228 may include silicon oxide, silicon nitride, silicon oxynitride, silicon carbonitride, silicon oxycarbonitride, high-K dielectric materials (e.g., aluminum oxide, hafnium oxide), other suitable materials, or combinations thereof, and may be deposited using plasma enhanced chemical vapor deposition (PECVD) or atomic layer deposition (ALD) or other suitable methods. In an embodiment, the dummy layers 228 include silicon oxide.

Referring to FIGS. 1 and 14A-14B, method 100 includes a block 116 where inner spacers 230 are formed. After forming the dummy layers 228, an etching process is performed to selectively recess the dummy layers 228 to form inner spacer recesses (now filled by inner spacers 230). The etching process selectively and partially recesses the dummy layers 228 to form inner spacer recesses, while the exposed channel members 208 are not significantly etched. In an embodiment where the channel members 208 consist essentially of silicon (Si) and the dummy layers 228 are formed of silicon oxide, the selective recess of the dummy layers 228 may be performed using a selective wet etch process or a selective dry etch process. The extent at which the dummy layers 228 are recessed is controlled by duration of the etching process. In an alternative embodiment, the etch back of the dielectric material layer for forming the dummy layers 228 and the selective and partial recess of the dummy layers 228 are conducted by performing a same etching process. Inner spacers 230 are then formed in the inner spacer recesses. In an example process, after the formation of the inner spacer recesses, an inner spacer material layer (not shown) is deposited over the semiconductor structure 200, including in the inner spacer recesses. The deposited inner spacer material layer is then etched back to remove excessive inner spacer material layer, thereby forming the inner spacers 230. The etch back process at block 108 may be a dry etching process that is similar to the dry etching process used in the formation of the source/drain openings 224a-224b. The inner spacers 230 track the shapes of the corresponding inner spacer recesses. The inner spacer material layer may include silicon oxide, silicon nitride, silicon oxycarbide, silicon oxycarbonitride, silicon carbonitride, metal nitride, or a suitable dielectric material.

Referring to FIGS. 1, 15A-15B, and 16, method 100 includes a block 120 where n-type source/drain features 232N and p-type source/drain features 232P are formed. The source/drain features are formed in the source/drain openings 224a-224b and coupled to the channel members 208 in the channel regions. In the present embodiments, n-type source/drain features 232N are formed in the source/drain openings 224a and in the first device region 200A, and p-type source/drain features 232P are formed in the source/drain openings 224b and in the second device region 200B. Exemplary n-type source/drain features 232N may include silicon, phosphorus-doped silicon, arsenic-doped silicon, antimony-doped silicon, or other suitable material and may be in-situ doped during the epitaxial process by introducing an n-type dopant, such as phosphorus, arsenic, or antimony, or ex-situ doped using a junction implant process. Exemplary p-type source/drain features 232P may include germanium, gallium-doped silicon germanium, boron-doped silicon germanium, or other suitable material and may be in-situ doped during the epitaxial process by introducing a p-type dopant, such as boron or gallium, or ex-situ doped using a junction implant process. In an embodiment, before forming the n-type source/drain features 232N and the p-type source/drain features 232P, an undoped semiconductor layer 234 (e.g., undoped silicon) may be formed to fill lower portions of the source/drain openings 224a-224b. In an embodiment, to further improve the performance of the n-type transistor 254T that will be formed in the first device region 200A, a dielectric layer 236 may be formed under the n-type source/drain feature 232N to reduce leakage current. For example, the dielectric layer 236 is disposed between the hybrid substrate 202 and the n-type source/drain feature 232N. The dielectric layer 236 may be a nitride layer, and its composition is different from that of the gate spacer 222. The second device region 200B may be free of the dielectric layer 236.

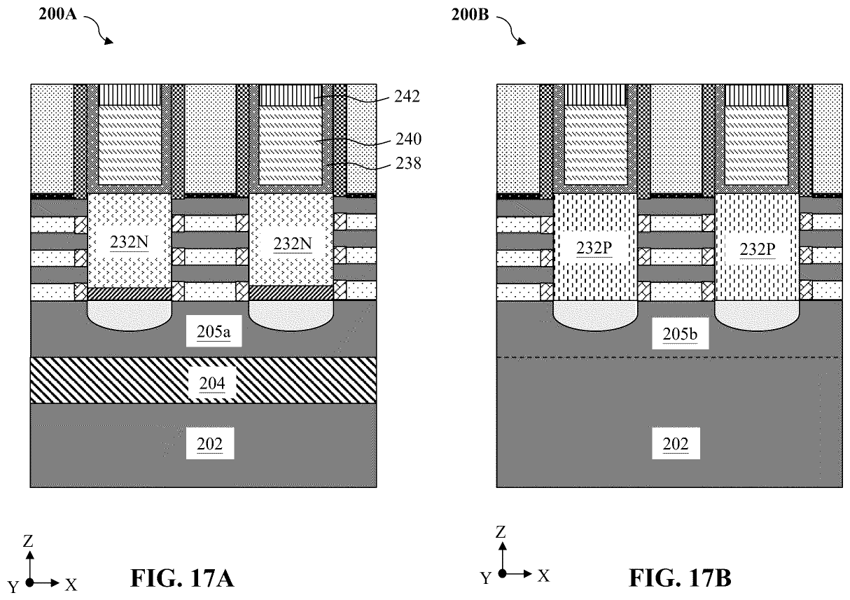

Referring to FIGS. 1, 17A-17B, 18A-18B, 19A-19B, and 20A-20B, method 100 includes a block 122 where isolation structures 248a-248b are formed adjacent to the n-type source/drain features 232N to cut the fin-shaped structure 210a. The isolation structures 248a-248b also define a region for the first semiconductor layer 204 to allow lattice of the first semiconductor layer 204 to relax, thereby providing tensile stress to the devices (e.g., n-type GAA transistor) formed in the first device region 200A above. With reference to FIGS. 17A-17B, after forming the n-type source/drain feature 232N and the p-type source/drain features 232P, a contact etch stop layer (CESL) 238 and an interlayer dielectric (ILD) layer 240 are formed over the semiconductor structure 200. The CESL 238 is configured to protect the various underlying components during subsequent fabrication processes and may include silicon nitride, silicon oxynitride, and/or other suitable materials and may be formed by atomic layer deposition (ALD), chemical vapor deposition (CVD), plasma-enhanced chemical vapor deposition (PECVD) process and/or other suitable deposition or oxidation processes. As shown in FIGS. 17A-17B, the CESL 238 may be formed on top surfaces of the n-type source/drain feature 232N and the p-type source/drain features 232P and sidewalls of the gate spacers 222. The ILD layer 240 is deposited by a CVD process, a PECVD process or other suitable deposition technique over the semiconductor structure 200 after the depositing of the CESL 238. The ILD layer 240 may include silicon oxide, a low-k dielectric material, tetraethyl orthosilicate (TEOS), doped silicon oxide (e.g., BPSG, FSG, PSG, BSG, etc.), other suitable dielectric materials, or combinations thereof. After forming the CESL 238 and the ILD layer 240, one or more chemical mechanical planarization (CMP) processes may be performed to planarize the top surface of the semiconductor structure 200 to expose dummy gate electrode 216b of the dummy gate stacks 216. In an embodiment, a dielectric cap 242 is formed on the ILD layer 240 to protect the ILD layer 240 during subsequent etching processes. A top surface of the dielectric cap 242 may be coplanar with a top surface of the CESL 238 and a top surface of the dummy gate electrode 216b.

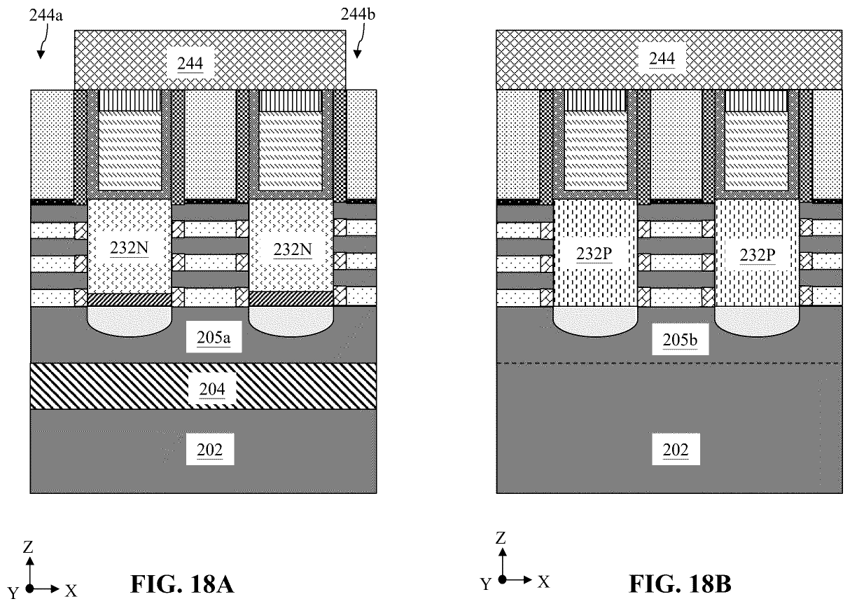

With reference to FIGS. 18A-18B, a patterned mask 244 (e.g., photoresist or hard mask) is formed over the intermediate structure 200. In this illustrated embodiment, the patterned mask 244 includes openings 244a-244b exposing two dummy gate electrodes over two channel regions of the fin-shaped structure 210a. One dummy gate electrode 216b is disposed between the two dummy gate electrodes exposed by the openings 244a-244b. The patterned mask 244 also covers the second device region 200B.

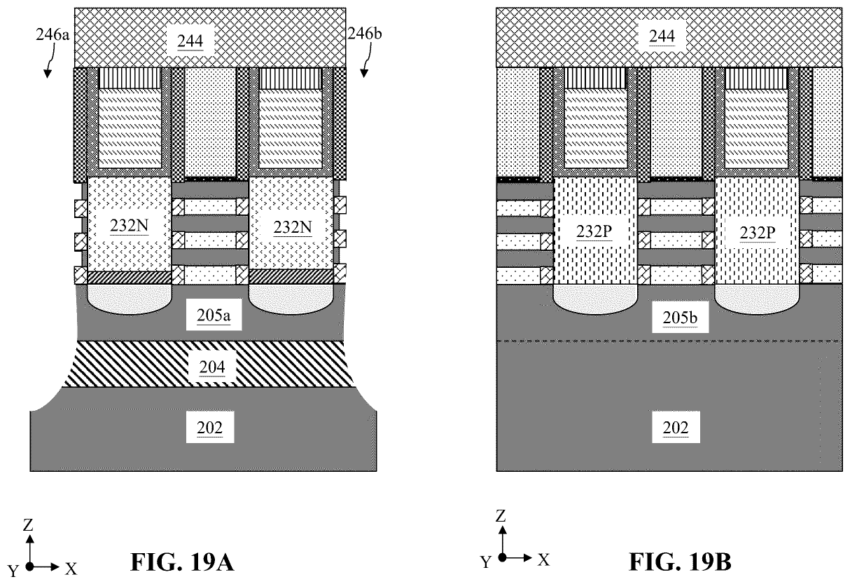

With reference to FIGS. 19A-19B, while using the patterned mask 244 as an etch mask, an etching process is performed to remove the two dummy gate electrodes and two channel regions of the fin-shaped structure 210a disposed directly under the openings 244a-244b, thereby forming trenches 246a and 246b. As illustrated by FIG. 19A, the trenches 246a and 246b extend through the first semiconductor layer 204 and extend into the substrate 202. In some embodiments, the two channel regions of the fin-shaped structure 210a are not fully removed. For example, as illustrated by FIG. 19A, there are some residues of the channel members 208 adjacent to and exposed by the trenches 246a and 246b.

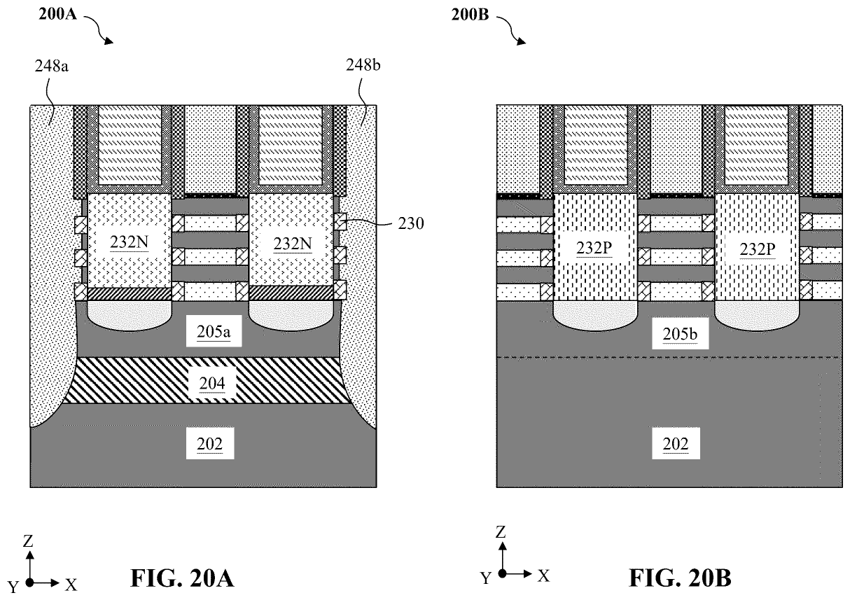

With reference to FIGS. 20A-20B, after forming the trenches 246a and 246b, a dielectric material is deposited over the intermediate structure 200 to fill the trenches 246a and 246b. A planarization process is then performed to remove excessive portions of the dielectric material to finalize the formation of the isolation structure 248a in the trench 246a and the isolation structure 248a in the trench 246b. The planarization process may also remove the dielectric cap 242 and other features laterally adjacent to the dielectric cap 242. The isolation structures 248a and 248b that are formed adjacent to the to-be-formed n-type transistor (e.g., n-type transistor 254N shown in FIG. 21A) may help sustain the strain generated by the first semiconductor layer 204 to improve carrier mobility. The isolation structures 248a-248b may each include a single layer structure or a multi-layer structure. As illustrated in FIG. 20A, the inner spacers 230 extend into the isolation structures 248a-248b.

Referring to FIGS. 1, 21A-21B, and 22, method 100 includes a block 124 where the dummy gate stacks 216 and the dummy layers 228 are replaced by gate structures 250 and 252. In an embodiment, after forming the isolation structures 248a and 248b, the dummy gate stacks 216 are selectively removed to form gate trenches. The gate trenches expose the channel regions previously covered by the dummy gate stacks 216. Etching process for selectively removing the dummy gate stacks 216 may include any suitable process, such as a dry etching process, a wet etching process, or combinations thereof. After the removal of the dummy gate stacks 216, the dummy layers 228 are selectively removed to form gate openings. The selective removal of the dummy layers 228 may be implemented by a selective dry etch, a selective wet etch, or other selective etching process. An example selective wet etch process may include use of diluted hydrofluoric acid (DHF) or a mixture of hydrofluoric acid (HF) and, ammonium fluoride (NH₄F). An example selective dry etch process may include use of anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), or a combination thereof. In some embodiments, the selective wet etching includes an APM etch (e.g., ammonia hydroxide-hydrogen peroxide-water mixture).

The gate structures 250-252 are then formed in the gate trenches and gate openings to wrap around the channel members 208. The gate structure 250 is formed in the first device region 200A, and the gate structure 252 are formed in the second device region 200B. While not explicitly shown, each of the gate structures 250-252 includes a gate dielectric layer (not separately labeled) and a gate electrode layer (not separately labeled) over the gate dielectric layer. In some embodiments, the gate dielectric layer includes an interfacial layer disposed on the channel members 208 and a high-k dielectric layer over the interfacial layer. Here, a high-k dielectric layer refers to a dielectric material having a dielectric constant greater than that of silicon dioxide, which is about 3.9. A low-k dielectric layer refers to a dielectric material having a dielectric constant no greater than that of silicon dioxide. In some embodiments, the interfacial layer includes silicon oxide. The high-k dielectric layer is then deposited over the interfacial layer using ALD, CVD, and/or other suitable methods. The high-k dielectric layer may include hafnium oxide. Alternatively, the high-k dielectric layer may include other high-k dielectrics, such as titanium oxide, hafnium zirconium oxide, tantalum oxide, hafnium silicon oxide, zirconium silicon oxide, lanthanum oxide, aluminum oxide, yttrium oxide, SrTiO₃, BaTiO₃, BaZrO, hafnium lanthanum oxide, lanthanum silicon oxide, aluminum silicon oxide, hafnium tantalum oxide, hafnium titanium oxide, (Ba,Sr)TiO₃ (BST), silicon nitride, silicon oxynitride, combinations thereof, or other suitable material. The gate electrode layer is then deposited over the gate dielectric layer using ALD, physical vapor deposition (PVD), CVD, e-beam evaporation, or other suitable methods. The gate electrode layer may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer may include titanium nitride, titanium aluminum, titanium aluminum nitride, tantalum nitride, tantalum aluminum, titanium aluminum nitride, tantalum aluminum carbide, tantalum carbonitride, aluminum, tungsten, nickel, titanium, ruthenium, cobalt, platinum, tantalum carbide, tantalum silicon nitride, copper, other refractory metals, or other suitable metal materials or a combination thereof. The gate structure 250 formed in the first device region 200A may include at least one n-type work function metal layer (e.g., titanium aluminum, titanium aluminum nitride), and the gate structure 252 formed in the second device region 200B may include at least one p-type work function metal layer (e.g., titanium nitride).

In the above embodiments described with reference to FIGS. 13A-22, the source/drain opening 224a (shown in FIG. 13A) does not expose the first semiconductor layer 204. In an alternative embodiment described with reference to FIGS. 23A-25B, the source/drain opening 224a (shown in FIG. 23A) may be formed to expose the first semiconductor layer 204. More specifically, with reference to FIGS. 13A-13B and 23A-23B, after removing the sacrificial layers 206 and forming the spaces 226, a patterned mask layer 280 is formed to cover features in the second device region 200B, while features in the first device region 200A are exposed. Then, while using the patterned mask layer 280 as an etch mask, an etching process 282 is performed to further vertically extend the source/drain opening 224a. The etching process 282 may be an anisotropic etching process. In an embodiment, etchant of the etching process 282 may be the same as the etchant of the etching process 220 performed at block 114. For example, etchant of the etching process 282 may include an oxygen-containing gas, hydrogen, a fluorine-containing gas (e.g., CF₄, SF₆, NF₃, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. The vertically extended source/drain opening 224a may be referred to as the source/drain opening 224a′. As illustrated by FIG. 23A, the source/drain opening 224a′ extends through the portion 205a of the second semiconductor layer 205 and into the first semiconductor layer 204. After performing the etching process 282, the patterned mask layer 280 may be selectively removed.

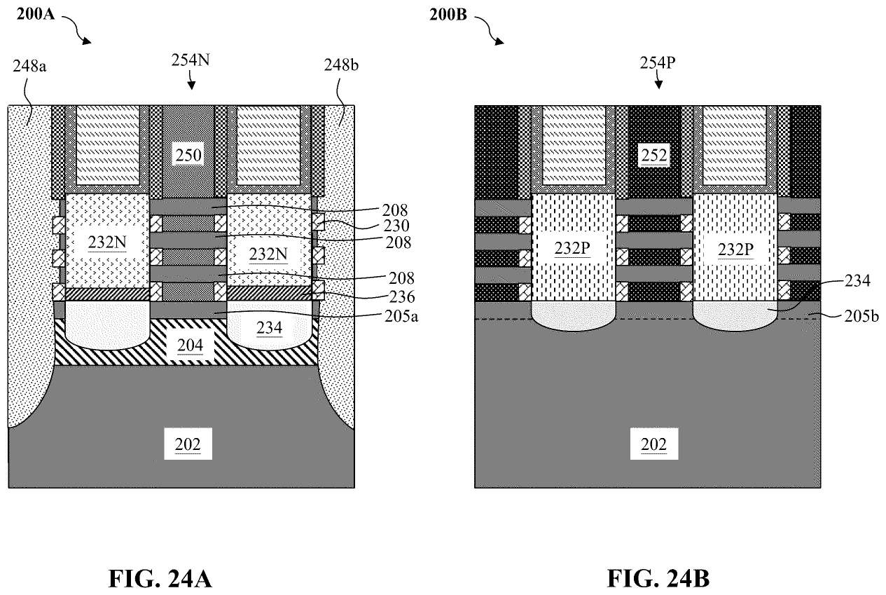

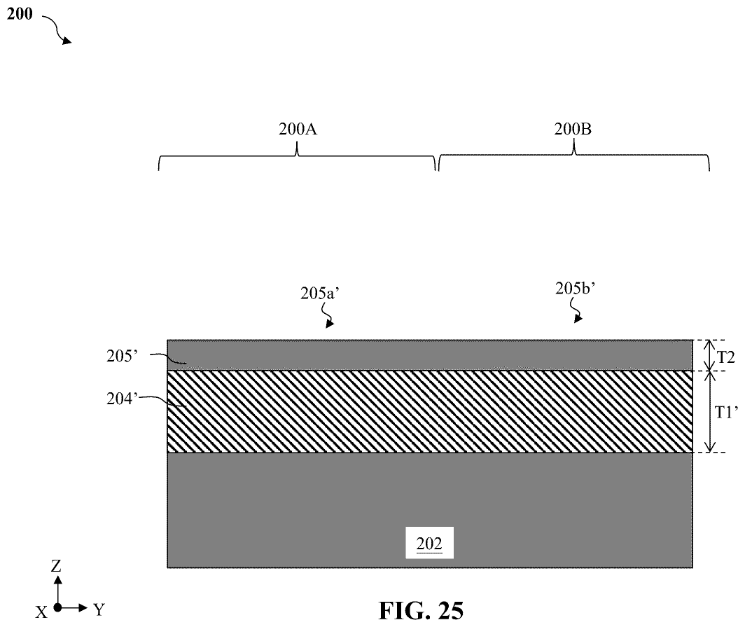

With reference to FIGS. 1 and 24A-24B, after forming the source/drain openings 224a′ in the first device region 200A and the source/drain openings 224b in the second device region 200B, as described above with reference to FIGS. 14A-14B, dummy layers 228 and inner spacers 230 are formed in the spaces 226. Then, with reference to FIGS. 24A-24B, operations at blocks 118, 120, 122, and 124 are performed to finish the fabrication of the n-type transistor 254N in the first device region 200A and p-type transistors 254P in the second device region 200B. In an embodiment, a thickness of the undoped semiconductor layer 234 of the n-type transistor 254N in the first device region 200A is greater than a thickness of the undoped semiconductor layer 234 of the p-type transistor 254P in the second device region 200B. In the above description, FIGS. 2-7 depict an exemplary method of forming the hybrid substrate 202H. FIGS. 25-28 depict a method of forming a hybrid substrate 202H′ that can be implemented to form the n-type transistors 254N and p-type transistors 254P thereon. With reference to FIG. 25, a semiconductor layer 204′ is epitaxially formed over the substrate 202 using an epitaxy process. Suitable epitaxy processes include vapor-phase epitaxy (VPE), ultra-high vacuum chemical vapor deposition (UHV-CVD), molecular beam epitaxy (MBE), and/or other suitable processes. The semiconductor layer 204′ can include various doped regions configured according to design requirements of semiconductor structure 200. In an embodiment, the semiconductor layer 204′ may include a doped region (not shown) having p-type dopants, such as boron, indium, other p-type dopant, or combinations thereof. An ion implantation process, a diffusion process, and/or other suitable doping process can be performed to form the doped region. In the present disclosure, to increase the performance of the n-type transistors, a composition of the semiconductor layer 204′ is selected such that it can induce strain into the n-type transistors. In various embodiments, the semiconductor layer 204′ may include silicon germanium, indium arsenide, gallium arsenide, gallium indium arsenide, or other suitable materials. In an embodiment, the semiconductor layer 204′ is formed of silicon germanium. A germanium content of the semiconductor layer 204′ may be about 20% to about 70%. If the germanium content is less than about 20%, then it may not induce enough strain to improve the device performance; and if the germanium content is greater than about 70%, a large number of dislocations may be formed during the epitaxial growth process of the semiconductor layer 204′, disadvantageously affecting the film quality of the semiconductor layer 204′. In an embodiment, the semiconductor layer 204′ has the thickness T1′.

Still referring to FIG. 25, after forming the semiconductor layer 204′, a semiconductor layer 205′ is epitaxially grown from the semiconductor layer 204′. The semiconductor layer 205′ may be deposited over the semiconductor layer 204′ using an epitaxy process. Suitable epitaxy processes include vapor-phase epitaxy (VPE), ultra-high vacuum chemical vapor deposition (UHV-CVD), molecular beam epitaxy (MBE), and/or other suitable processes. In an embodiment, the semiconductor layer 205′ has the thickness T2. In the present disclosure, to generate tensile strain, a composition of the semiconductor layer 204′ is selected such that it has a smaller lattice constant than the semiconductor layer 204′. In an embodiment, the semiconductor layer 205′ is formed of silicon. The semiconductor layer 205′ has a first portion 205a′ in the first device region 200A and a second portion 205b′ laterally adjacent to the first portion 205a′ and in the second device region 200B. Due to the existence of the semiconductor layer 204′, lattice structure of the semiconductor layer 205′ of the second semiconductor layer 205 may be stretched and undergo tensile strain. The semiconductor layer 205′ can include various doped regions configured according to design requirements of semiconductor structure 200. In this embodiment, n-type transistors will be formed over the first portion 205a′, and the semiconductor layer 205′ may include a doped region (not shown) in the first portion 205a′. The doped region in the first portion 205a′ includes p-type dopants, such as boron, indium, other p-type dopant, or combinations thereof. An ion implantation process, diffusion process, and/or other suitable doping process can be performed to form the doped region in the first portion 205a′. The second portion 205b′ may be undoped or doped. If doped, dopant polarity of the second portion 205b′ may be the same as or different from that of the first portion 205a′. That is, the second portion 205b′ may include n-type dopants or p-type dopants, or may be free of dopants.

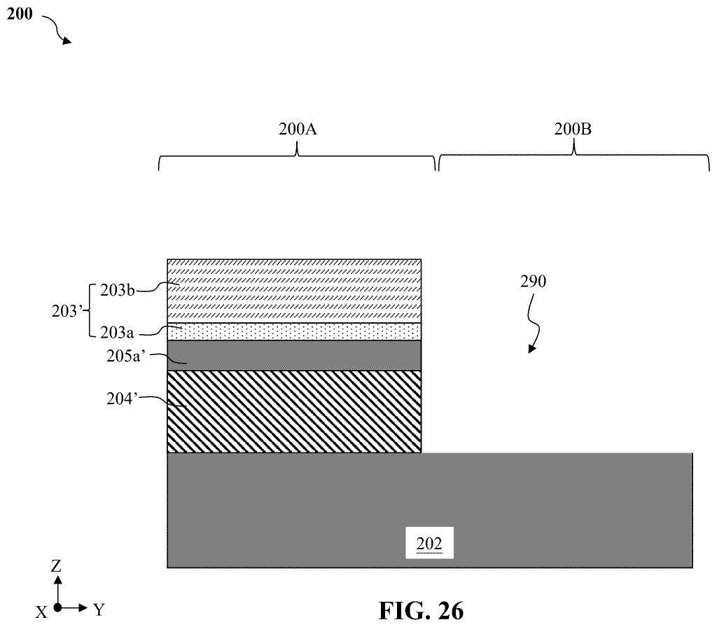

Referring to FIG. 26, after forming the semiconductor layer 204′ and the semiconductor layer 205′, a patterned mask 203′ is formed over the semiconductor layer 205′ and in the first device region 200A. The composition and formation of the patterned mask 203′ may be similar to the patterned hard mask 203. As illustrated by FIG. 26, the patterned mask 203′ covers the first portion 205a′. While using the patterned mask 203′ as an etch mask, an etching process is performed to remove portions of the semiconductor layers 204′ and 205′ in the second device region 200B, thereby forming a trench 290. The trench 290 exposes a portion of a top surface of the substrate 202, sidewalls of the semiconductor layer 204′ and 205′. In some embodiments, the trench 290 may extend into the substrate 202.

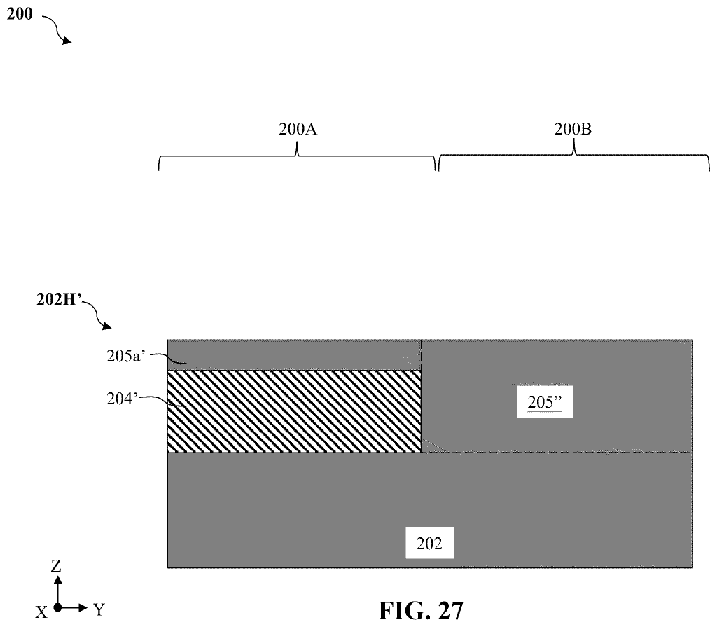

Referring to FIG. 27, after forming the trench 290, a semiconductor layer 205″ is epitaxially formed over the substrate 202 to substantially fill the trench 290. Composition and formation of the semiconductor layer 205″ may be similar to those of the semiconductor layer 205′, and repeated description is omitted for reason of simplicity. In some embodiments, the semiconductor layer 205″ can include n-type doped regions configured according to design requirements of semiconductor structure 200. N-type doped regions may include n-type dopants, such as phosphorus, arsenic, other n-type dopant, or combinations thereof. An ion implantation process, a diffusion process, and/or other suitable doping process can be performed to form the n-type doped regions. After forming the semiconductor layer 205″, the patterned mask 203′ may be removed. In some embodiments, a planarization process may be performed after the removing of the patterned mask 203′. The hybrid substrate 202H′ that includes the substrate 202, the semiconductor layer 204′ in the first device region 200A, the portion 205a′ of the semiconductor layer 205′ in the first device region 200A and on the semiconductor layer 204′, and the semiconductor layer 205″ in the second device region 200B are thus formed. Operations at blocks 108-124 may be then performed to form the n-type transistors 254N and p-type transistors 254P in and over the hybrid substrate 202H′.

Although not intended to be limiting, one or more embodiments of the present disclosure provide many benefits to semiconductor devices and the formation thereof. In some embodiments, the present disclosure provides methods for forming gate-all-around transistors with improved performance (e.g., reduced performance gap between NFETs and PFETs, enhanced electron mobility) by providing a substrate including a stressor under the NFET.

The present disclosure provides for many different embodiments. Semiconductor structures and methods of fabrication thereof are disclosed herein. In one exemplary aspect, the present disclosure is directed to a method. The method includes forming a hybrid substrate comprising a first region and a second region, the first region comprising a second semiconductor layer embedded in a first semiconductor layer, the second region comprising the first semiconductor layer and being free of the second semiconductor layer, the first semiconductor layer and the second semiconductor layer having different compositions, epitaxially forming a vertical stack of alternating channel layers and sacrificial layers over the hybrid substrate, patterning the vertical stack and a top portion of the hybrid substrate to form a first fin-shaped structure and a second fin-shaped structure, the first fin-shaped structure comprising the second semiconductor layer, forming a first source/drain opening extending into the first fin-shaped structure, forming a second source/drain opening extending into the second fin-shaped structure, forming a first source/drain feature in the first source/drain opening, forming a second source/drain feature in the second source/drain opening, the first and second source/drain features having opposite dopant polarities, selectively removing the sacrificial layers to form gate openings, and forming gate structures in the gate openings.

In some embodiments, the second semiconductor layer and the sacrificial layers may include silicon germanium. In some embodiments, the method may also include, before forming the gate structures, forming dummy layers in the gate openings, forming inner spacers adjoining the dummy layers, and after the forming of the second source/drain feature, selectively removing the dummy layers. In some embodiments, the forming of the hybrid substrate may include forming a trench in a bulk semiconductor layer, forming a semiconductor material layer in and over the trench, planarizing the semiconductor material layer and the bulk semiconductor layer until a top surface of the semiconductor material layer is coplanar with a top surface of the bulk semiconductor layer, and epitaxially forming a third semiconductor layer on the semiconductor material layer and the bulk semiconductor layer, wherein the semiconductor material layer and the second semiconductor layer are formed of a same material. In some embodiments, the bulk semiconductor layer and the third semiconductor layer are portions of the first semiconductor layer. In some embodiments, the method may also include forming an isolation feature extending from a lower portion of the first fin-shaped structure to a lower portion of the second fin-shaped structure, and a top surface of the second semiconductor layer is below a top surface of the isolation feature. In some embodiments, a bottom surface of the first source/drain opening is above the second semiconductor layer. In some embodiments, the method may also include forming a dielectric layer disposed between the first source/drain feature and the hybrid substrate. In some embodiments, the method may also include, after the forming of the first source/drain feature, forming an isolation structure extending through the first fin-shaped structure and adjacent to the first source/drain feature.

In another exemplary aspect, the present disclosure is directed to a method. The method includes forming a patterned hard mask over a substrate, the patterned hard mask comprising an opening exposing a portion of the substrate, removing the portion of the substrate, thereby forming a trench in the substrate, epitaxially forming a first semiconductor layer in and over the trench, wherein the first semiconductor layer and the substrate comprise different compositions, after the epitaxially forming of the first semiconductor layer, selectively removing the patterned hard mask, planarizing the first semiconductor layer and the substrate, after the planarizing, forming a second semiconductor layer on the first semiconductor layer and the substrate, and forming an n-type gate-all-around (GAA) transistor over the first semiconductor layer and the substrate.

In some embodiments, the substrate and the second semiconductor layer may include silicon, and the first semiconductor layer may include silicon germanium. In some embodiments, the forming of the n-type GAA transistor may include forming a plurality of channel layers interleaved by a plurality of sacrificial layers, patterning the plurality of channel layers, the plurality of sacrificial layers, the first and second semiconductor layers, and a top portion of the substrate to form a fin, forming source/drain features coupled to the plurality of channel layers, and replacing the sacrificial layers with a gate structure. In some embodiments, the replacing of the sacrificial layers with the gate structure may include replacing the sacrificial layers with oxide layers and replacing the oxide layers with the gate structure. In some embodiments, the source/drain features are disposed over the first semiconductor layer. In some embodiments, the method may also include forming a dielectric layer disposed between the source/drain features and the first semiconductor layer. In some embodiments, the method may also include forming an isolation structure adjacent to the n-type GAA transistor, and a top surface of the isolation structure is above a channel region of the n-type GAA transistor, and a bottom surface of the isolation structure is below a bottom surface of the first semiconductor layer. In yet another exemplary aspect, the present disclosure is directed to a semiconductor structure. The semiconductor structure includes

In another exemplary aspect, the present disclosure is directed to a semiconductor structure. The semiconductor structure including a substrate comprising a second semiconductor material layer embedded in a first semiconductor material layer, the first semiconductor material layer and the second semiconductor material layer having different compositions, and an n-type transistor over the substrate and comprising a plurality of nanostructures over the second semiconductor material layer, a gate structure wrapping around and over the plurality of nanostructures, and a first n-type source/drain feature and a second n-type source/drain feature coupled to the plurality of nanostructures and extending over the second semiconductor material layer.

In some embodiments, the semiconductor structure may also include a first isolation structure adjacent to the first n-type source/drain feature and extending through the second semiconductor material layer, and a second isolation structure adjacent to the second n-type source/drain feature and extending through the second semiconductor material layer. In some embodiments, the semiconductor structure may also include a dielectric layer disposed vertically between the first n-type source/drain feature and the second semiconductor material layer. In some embodiments, the first semiconductor material layer may include silicon, and the second semiconductor material layer may include silicon germanium, and a germanium content of the second semiconductor material layer is about 30% to about 70%.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure. For example, by implementing different thicknesses for the bit-line conductor and word line conductor, one can achieve different resistances for the conductors. However, other techniques to vary the resistances of the metal conductors may also be utilized as well.

What is claimed is:

1. A method, comprising:
forming a hybrid substrate comprising a first region and a second region, the first region comprising a second semiconductor layer embedded in a first semiconductor layer, the second region comprising the first semiconductor layer and being free of the second semiconductor layer, wherein the first semiconductor layer and the second semiconductor layer have different compositions;
epitaxially forming a vertical stack of alternating channel layers and sacrificial layers over the hybrid substrate;
patterning the vertical stack and a top portion of the hybrid substrate to form a first fin-shaped structure and a second fin-shaped structure, wherein the first fin-shaped structure comprises the second semiconductor layer;
forming a first source/drain opening extending into the first fin-shaped structure;
forming a second source/drain opening extending into the second fin-shaped structure;
forming a first source/drain feature in the first source/drain opening;
forming a second source/drain feature in the second source/drain opening, the first and second source/drain features having opposite dopant polarities;
selectively removing the sacrificial layers to form gate openings; and
forming gate structures in the gate openings.

2. The method of claim 1, wherein the second semiconductor layer and the sacrificial layers comprise silicon germanium.

3. The method of claim 1, further comprising:
before forming the gate structures, forming dummy layers in the gate openings;
forming inner spacers adjoining the dummy layers; and
after the forming of the second source/drain feature, selectively removing the dummy layers.

4. The method of claim 1, wherein the forming of the hybrid substrate comprises:
forming a trench in a bulk semiconductor layer;
forming a semiconductor material layer in and over the trench;
planarizing the semiconductor material layer and the bulk semiconductor layer until a top surface of the semiconductor material layer is coplanar with a top surface of the bulk semiconductor layer; and
epitaxially forming a third semiconductor layer on the semiconductor material layer and the bulk semiconductor layer, wherein the semiconductor material layer and the second semiconductor layer are formed of a same material.

5. The method of claim 4, wherein the bulk semiconductor layer and the third semiconductor layer are portions of the first semiconductor layer.

6. The method of claim 1, further comprising:
forming an isolation feature extending from a lower portion of the first fin-shaped structure to a lower portion of the second fin-shaped structure,
wherein a top surface of the second semiconductor layer is below a top surface of the isolation feature.

7. The method of claim 6, wherein a bottom surface of the first source/drain opening is above the second semiconductor layer.

8. The method of claim 1, further comprising:
forming a dielectric layer disposed between the first source/drain feature and the hybrid substrate.

9. The method of claim 1, further comprising:
after the forming of the first source/drain feature, forming an isolation structure extending through the first fin-shaped structure and adjacent to the first source/drain feature.

10. A method, comprising:
forming a patterned hard mask over a substrate, the patterned hard mask comprising an opening exposing a portion of the substrate;
removing the portion of the substrate, thereby forming a trench in the substrate;
epitaxially forming a first semiconductor layer in and over the trench, wherein the first semiconductor layer and the substrate comprise different compositions;
after the epitaxially forming of the first semiconductor layer, selectively removing the patterned hard mask;
planarizing the first semiconductor layer and the substrate;
after the planarizing, forming a second semiconductor layer on the first semiconductor layer and the substrate; and
forming an n-type gate-all-around (GAA) transistor over the first semiconductor layer and the substrate.

11. The method of claim 10, wherein the substrate and the second semiconductor layer comprise silicon, and the first semiconductor layer comprises silicon germanium.

12. The method of claim 10, wherein the forming of the n-type GAA transistor comprises:
forming a plurality of channel layers interleaved by a plurality of sacrificial layers;
patterning the plurality of channel layers, the plurality of sacrificial layers, the first and second semiconductor layers, and a top portion of the substrate to form a fin;
forming source/drain features coupled to the plurality of channel layers; and
replacing the sacrificial layers with a gate structure.

13. The method of claim 12, wherein the replacing of the sacrificial layers with the gate structure comprises:
replacing the sacrificial layers with oxide layers; and
replacing the oxide layers with the gate structure.

14. The method of claim 12, wherein the source/drain features are disposed over the first semiconductor layer.

15. The method of claim 12, further comprising:
forming a dielectric layer disposed between the source/drain features and the first semiconductor layer.

16. The method of claim 10, further comprising:
forming an isolation structure adjacent to the n-type GAA transistor,
wherein a top surface of the isolation structure is above a channel region of the n-type GAA transistor, and a bottom surface of the isolation structure is below a bottom surface of the first semiconductor layer.

17. A semiconductor structure, comprising:
a substrate comprising a second semiconductor material layer embedded in a first semiconductor material layer, the first semiconductor material layer and the second semiconductor material layer having different compositions; and
an n-type transistor over the substrate and comprising:
a plurality of nanostructures over the second semiconductor material layer,
a gate structure wrapping around and over the plurality of nanostructures, and
a first n-type source/drain feature and a second n-type source/drain feature coupled to the plurality of nanostructures and extending over the second semiconductor material layer.

18. The semiconductor structure of claim 17, further comprising:
a first isolation structure adjacent to the first n-type source/drain feature and extending through the second semiconductor material layer; and
a second isolation structure adjacent to the second n-type source/drain feature and extending through the second semiconductor material layer.

19. The semiconductor structure of claim 17, further comprising:
a dielectric layer disposed vertically between the first n-type source/drain feature and the second semiconductor material layer.

20. The semiconductor structure of claim 17, wherein the first semiconductor material layer comprises silicon, and the second semiconductor material layer comprises silicon germanium, and a germanium content of the second semiconductor material layer is about 30% to about 70%.
